(19) United States
(12) Patent Application Publication
(10) Pub. No.: US 2020/0150789 A1
(43) Pub. Date: May 14, 2020

(54) FLEXIBLE CONDUCTIVE DISPLAY FILM

(71) Applicant: 3M INNOVATIVE PROPERTIES COMPANY, St. Paul, MN (US)

(72) Inventors: Joseph W. WOODY, V, Woodbury, MN (US); David Scott THOMPSON, Bayport, MN (US); Matthew S. STAY, Minneapolis, MN (US); Michael A. JOHNSON, Stillwater, MN (US); Daniel J. THEIS, Mahtomedi, MN (US); Ann Marie GILMAN, Woodbury, MN (US); Shawn C. DODDS, St. Paul, MN (US)

(21) Appl. No.: 16/632,788

(22) PCT Filed: Jul. 19, 2018
(86) PCT No.: PCT/IB2018/055387

§ 371 Date: Jan. 21, 2020

Related U.S. Application Data
(60) Provisional application No. 62/535,765, filed on Jul. 21, 2017.

(51) Int. Cl. G06F 3/041

(52) U.S. Cl. CPC G06F 3/041; H01L 27/32

(57) ABSTRACT

A display film includes a transparent energy dissipation layer having a glass transition temperature of 27 degrees Celsius or less and a Tan Delta peak value of 0.5 or greater, and a transparent conductor layer disposed on the transparent energy dissipation layer. The conductive display films including transparent conductors and a flexible substrate that can protect a display window and survive folding tests intact while maintaining the desired electric conductive properties.

### BACKGROUND

Displays and electronic devices have evolved to be curved, bent, or folded and provide new user experiences. These device architectures may include flexible organic light emitting diodes (OLEDs), plastic liquid crystal displays (LCDs) and the like, for example.

In order to realize flexible displays and protect elements in the displays, a flexible cover sheet or flexible window film replaces a conventional glass cover sheet. This flexible cover sheet has several design parameters such as; high visible light transmission, low haze, excellent scratch resistance and impact resistance, in order to protect the elements included in the display devices. In some cases, the flexible cover sheet may need to withstand thousands of folding events around a tight bend radius (about 5 mm or less) without damage. In other cases, the flexible cover sheet must be able to unfold without leaving a visible crease after being bent at elevated temperature and humidity.

A variety of hard coated plastic substrates have been explored. More exotic materials like hard coated colorless transparent polyimide films have also been shown to have high hardness and good scratch resistance. However, many hard-coated films fail to withstand folding events around a tight bend radius without showing visible damage and fail to provide adequate impact resistance.

Durable and flexible touch sensor constructions are also useful and typically include conductors on or in a polymer film. Typical commercial conductors are indium tin oxide (ITO) traces or metal mesh. The polymer may be substrates such as cyclo-olefin polymers or polyesters such as polyethylene terephthalate (PET). These constructions, however, do not often survive bending or folding events.

### SUMMARY

The present disclosure relates to conductive display films including transparent conductors and a flexible substrate that can protect a display window and survive folding tests intact while maintaining the desired electric conductive properties. The conductive display film may also maintain optical properties of a display film while providing scratch resistance and impact resistance to the display. These conductive display films may form a portion of a touch sensor display that survive bending or folding events.

In one aspect, a display film includes a transparent energy dissipation layer having a glass transition temperature of 27 degrees Celsius or less and a Tan Delta peak value of 0.5 or greater, and a transparent conductor layer disposed on the transparent energy dissipation layer.

In another aspect, a display film includes a transparent energy dissipation layer having a glass transition temperature of 27 degrees Celsius or less and a Tan Delta peak value of 0.5 or greater, and defining a first major surface and an opposing second major surface. A transparent conductor layer is disposed on the first major surface of the transparent energy dissipation layer. A protective layer is disposed on the second major surface.

In another aspect, a display film includes an optical display and a display film, as described herein, fixed to the optical display.

The transparent conductor layer may include a plurality of nanowires. The nanowires may be disposed on top of the transparent energy dissipation layer or the nanowires may be embedded into the transparent energy dissipation layer. The nanowires may or may not form a pattern or regular pattern. The nanowires may have a diameter (or largest lateral width) of 100 nanometers or less. The nanowires may be silver nanowires.

A second transparent conductor layer may be disposed on the transparent energy dissipation layer such that the transparent energy dissipation layer separates the transparent conductor layers. The second transparent conductor layer may be formed of a similar material as the transparent conductor layer. The second transparent conductor layer may include a plurality of nanowires extending in a direction orthogonal to the direction of the nanowires of the opposing transparent conductor layer.

The transparent energy dissipation layer may be formed of a cross-linked polyurethane or cross-linked polyurethane acrylate or cross-linked polyurethane and polyacrylate. The display film may have a haze value of less than 5%, or less than 3%, or less than 2%, or less than 1%, and the display film may have a visible light transmission value greater than 85%, or greater than 90%, and the display film may have a clarity value greater than 90%, or greater than 95% or greater than 98%. The transparent energy dissipation layer may have a glass transition temperature of 25 degrees Celsius or less, or 20 degrees Celsius or less, 15 degrees Celsius or less, 10 degrees Celsius or less, 5 degrees Celsius or less, or 0 degrees Celsius or less, or −5 degrees Celsius or less, or in a range from −40 to 15 degrees Celsius, or in a range from −30 to 15 degrees Celsius, or in a range from −30 to 10 degrees Celsius, or in a range from −30 to 5 degrees Celsius, or in a range from −30 to 0 degrees Celsius, or in a range from −20 to 0 degrees Celsius. The transparent energy dissipation layer may have a Tan Delta peak value of 0.8 or greater, or 1.0 or greater, or 1.2 or greater, or in a range from 0.5 to 2.5, or in a range from 1 to 2.5.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 is a schematic diagram side elevation view of an illustrative conductive display film;

FIG. 2 is a schematic diagram side elevation view of another illustrative conductive display film;

FIG. 3 is a perspective schematic diagram side elevation view of another illustrative conductive display film;

FIG. 4 is a schematic diagram side elevation view of another illustrative conductive display film;

FIG. 5 is a perspective schematic diagram side elevation view of another illustrative conductive display film;

FIG. 6 is a schematic diagram side elevation view of another illustrative conductive display film;

FIG. 7 is a schematic diagram side elevation view of another illustrative conductive display film;

FIG. 8 is a schematic diagram side elevation view of an illustrative conductive display film on an optical display forming an article; and

FIG. 9 is a schematic diagram perspective view of an illustrative folding article including an illustrative conductive display film.

### DETAILED DESCRIPTION

In the following detailed description, reference is made to the accompanying drawings that form a part hereof, and in which are shown by way of illustration for several specific embodiments. It is to be understood that other embodiments are contemplated and may be made without departing from the scope or spirit of the present disclosure. The following detailed description, therefore, is not to be taken in a limiting sense.

All scientific and technical terms used herein have meanings commonly used in the art unless otherwise specified. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range. Herein, the terms “up to” or “no greater than” a number (e.g., up to 50) includes the number (e.g., 50), and the term “no less than” a number (e.g., no less than 5) includes the number (e.g., 5).

The terms “fixed” or “coupled” or “connected” refer to elements being attached to each other either directly (in direct contact with each other) or indirectly (having one or more elements between and attaching the two elements).

Terms related to orientation, such as “top”, “bottom”, “side”, and “end”, are used to describe relative positions of components and are not meant to limit the orientation of the embodiments contemplated. For example, an embodiment described as having a “top” and “bottom” also encompasses embodiments thereof rotated in various directions unless the content clearly dictates otherwise.

Reference to “one embodiment,” “an embodiment,” “certain embodiments,” or “some embodiments,” etc., means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure.

As used in this specification and the appended claims, the singular forms “a”, “an”, and “the” encompass embodiments having plural referents, unless the content clearly dictates otherwise.

As used in this specification and the appended claims, the term “or” is generally employed in its sense including “and/or” unless the content clearly dictates otherwise.

As used herein, “have”, “having”, “include”, “including”, “comprise”, “comprising” or the like are used in their open-ended sense, and generally mean “including, but not limited to”. It will be understood that “consisting essentially of”, “consisting of”, and the like are subsumed in “comprising,” and the like.

The terms “display film”, “protective film”, and “protective display film” are herein used interchangeably.

“Transparent substrate” or “transparent layer” refers to a substrate or layer that has a high light transmission (typically greater than 90%) over at least a portion of the surface of the substrate over at least a portion of the light spectrum with wavelengths of about 350 to about 1600 nanometers, including the visible light spectrum (wavelengths of about 380 to about 750 nanometers).

“Polyurethane” refers to polymers prepared by the step-growth polymerization of hydroxyl-functional materials (materials containing hydroxyl groups —OH) with isocyanate-functional materials (materials containing isocyanate groups —NCO) and therefore contain urethane linkages (—O(CO)—NH—), where (CO) refers to a carbonyl group (C═O). The term may include “polyurethane-ureas” in which both urethane linkages and urea linkages are present.

“Polyacrylate” refers to polyacrylate or poly(meth)acrylate polymers prepared by the free radical polymerization of a precursor containing the reactive vinyl groups or vinylidene groups within acrylate end groups or (meth)acrylate end groups. Polyacrylate precursors include urethane acrylates which include both urethane and acrylate segments in the polymer chain.

“Polyurethane acrylate” refers to a polymer that includes primarily urethane and acrylate moieties or segments.

The phrase “glass transition temperature” refers herein to the onset of the glass transition as determined by the location of the peak for E″, where the polyurethane sample was characterized by DMA at an oscillation of 0.2% strain and 1 Hz throughout a temperature ramp from −50° C. to 200° C. at a rate of 2° C. per minute.

The phrase “Tan Delta peak value” and peak temperature is measured according to the DMA analysis described in the Examples.

The present disclosure relates to conductive display films including transparent conductors (i.e., electrical conductors) and a flexible substrate that can protect a display window and survive folding tests intact. The conductive display film may maintain optical properties of a display film while providing scratch resistance and impact resistance to the display. These conductive display films may form a portion of a touch sensor display that survive bending or folding events. The transparent conductors may include a plurality of nanowires. The nanowires may be disposed on top of the transparent energy dissipation layer or the nanowires may be embedded into the transparent energy dissipation layer. The nanowires may or may not form a pattern or regular pattern. The nanowires may have a diameter of 100 nanometers or less, and may have an aspect ratio of at least 10:1, or at least 100:1, or at least 1000:1. The nanowires may be silver nanowires. The transparent energy dissipation layer may be formed of a cross-linked polyurethane or cross-linked polyurethane acrylate or cross-linked polyurethane and polyacrylate. The display film may have a haze value of less than 5%, or less than 3%, or less than 2%, or less than 1%, and the display film may have a visible light transmission value greater than 85%, or greater than 90%, and the display film may have a clarity value greater than 90%, or greater than 95% or greater than 98%. The transparent energy dissipation layer may have a glass transition temperature of 45 degrees Celsius or less, 40 degrees Celsius or less, 35 degrees Celsius or less, 30 degrees Celsius or less, 27 degrees Celsius or less, 20 degrees Celsius or less, 10 degrees Celsius or less, or 0 degrees Celsius or less, or −5 degrees Celsius or less, or in a range from −40 to 15 degrees Celsius, or in a range from −30 to 15 degrees Celsius, or in a range from −30 to 10 degrees Celsius, or in a range from −30 to 5 degrees Celsius, or in a range from −30 to 0 degrees Celsius, or in a range from −20 to 0 degrees Celsius. The transparent energy dissipation layer may have a Tan Delta peak value of 0.8 or greater, or 1.0 or greater, or 1.2 or greater, or in a range from 0.5 to 2.5, or in a range from 1 to 2.5. While the present disclosure is not so limited, an appreciation of various aspects of the disclosure will be gained through a discussion of the examples provided below.

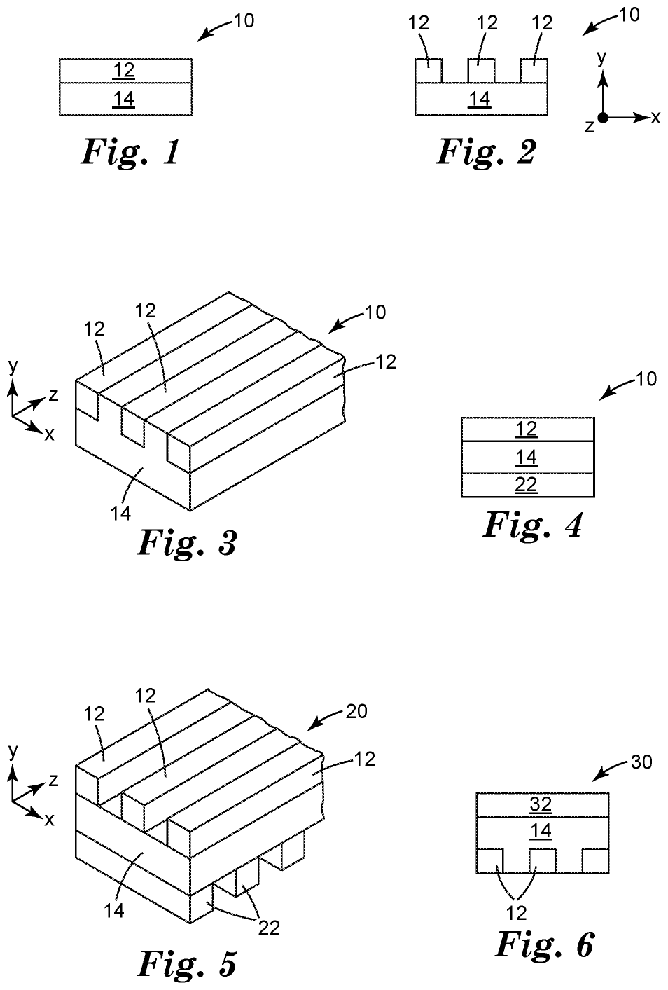

FIG. 1 is a schematic diagram side elevation view of an illustrative conductive display film 10. FIG. 2 is a schematic diagram side elevation view of another illustrative conductive display film 10 illustrating a plurality of transparent conductor layer 12 formed on the transparent energy dissipation layer 14. FIG. 3 is a perspective schematic diagram side elevation view of another illustrative conductive display film 10 where the transparent conductors 12 are embedded in the transparent energy dissipation layer 14.

The conductive display film 10 includes a transparent energy dissipation layer 14 having a glass transition temperature of 45 degrees Celsius or less, 40 degrees Celsius or less, 35 degrees Celsius or less, 30 degrees Celsius or less, 27 degrees Celsius or less, and a Tan Delta peak value of 0.5 or greater, and a transparent conductor layer 12 disposed on the transparent energy dissipation layer 14. The transparent conductor layer 12 may be formed of a plurality of transparent conductors that extend along a major surface of the transparent energy dissipation layer 14. The transparent conductor layers 12 may extend in a parallel arrangement or non-parallel arrangement. The transparent conductor layers 12 may form a regular pattern or a non-regular pattern. The transparent conductor layers 12 may form a regular mesh pattern or a non-regular mesh pattern.

The transparent conductor layer 12 may form of a three-dimensional random matrix of nanowires in a binder. The transparent conductor layer 12 may be coated onto the substrate or energy dissipation layer 14. The coating of nanowires in binder results in contact between individual nanowires in the binder to produce transparent conductor layer 12. Nanowires are touching and are above the percolation threshold. The nanowires may reside in a binder that separates the wires but provides a stable coating and may form a “a nest of wires”. The transparent conductor layers 12 may have a dry thickness in a range from 200 nanometers to about 10 micrometers, or from about 200 nanometers to about 6 micrometers, or from about 500 nanometers to about 3 micrometers.

The transparent conductor layer 12 may appear transparent or invisible to human perception. The nanowires forming the transparent conductor layer 12 may have an aspect ratio (largest lateral dimension to length) of at least 10, or at least 100, or at least 1000. The nanowires forming the transparent conductor layer 12 may have a largest lateral dimension, such as height, width, and/or diameter (if a circular cross-section) that is from 25 to 200 nanometers in lateral distance, or from 50 to 150 nanometers in lateral distance, or from 75 to 125 nanometers in lateral distance, or less than 100 nanometers in lateral distance, or from 50 to 100 nanometers in lateral distance. The length of individual nanowires may be from 1 to 100 micrometers.

The transparent conductor layer 12 may be patterned to produce conductive regions and non-conductive regions on the substrate or energy dissipation layer 14 (as shown in FIGS. 2, 3, 5, 6, 7, and 8). The transparent conductor layer 12 may be continuous or may comprise a patterned region with features designed to make the patterned region no visible, for example a herringbone pattern of wires. In some cases, the entire region is patterned where the wires are connected in in certain regions but isolated and not connected in the region meant to be not conductive and then the entire pattern is transferred.

The transparent conductor layer 12 (or nanowires) may be formed of any conductive material such as a metal, for example. Suitable metal nanowires can be based on any metal, including without limitation, silver, gold, copper, nickel, and gold-plated silver. The transparent conductor layer 12 may be formed of a silver material or silver.

The metal nanowires can be prepared by known methods in the art. In particular, silver nanowires can be synthesized through solution-phase reduction of a silver salt (e.g., silver nitrate) in the presence of a polyol (e.g., ethylene glycol) and polyvinyl pyrrolidone). Large-scale production of silver nanowires of uniform size can be prepared according to the methods described in, e.g., Xia, Y. et al., Chem. Mater. (2002), 14, 4736-4745, and Xia, Y. et al., Nanoletters (2003) 3(7), 955-960. More methods of making nanowires, such as using biological templates, are disclosed in PCT International Pub. No. WO 2007/022226.

The nanowires may be dispersed in a liquid and a nanowire layer on the transparent energy dissipation layer or substrate may be formed by coating the liquid containing the nanowires onto the transparent energy dissipation layer or substrate and then allowing the liquid to evaporate (dry) or cure. The nanowires may be dispersed in a liquid to facilitate more uniform deposition onto a substrate layer such as the transparent energy dissipation layer or onto a transfer substrate by using a coater or sprayer.

The nanowire dispersion may be coated onto a substrate such as a protective layer or hardcoat layer to form the transparent conductor layer and then the energy dissipation layer may be coated or disposed onto the coated and preferably patterned transparent conductor layer to form the display film. Alternatively, the nanowire dispersion may be coated onto a substrate that is a removable layer to form the transparent conductor layer. Then the transparent conductor layer is preferably patterned and then the energy dissipation layer may be coated or disposed onto the patterned transparent conductor layer.

Any non-corrosive liquid in which the nanowires can form a stable dispersion (also called “nanowire dispersion”) can be used. Preferably, the nanowires are dispersed in water, an alcohol, a ketone, ethers, hydrocarbons or an aromatic solvent (benzene, toluene, xylene, etc.). Preferably, the liquid is volatile, having a boiling point of no more than 200 degrees C., no more than 150 degrees C., or no more than 100 degrees C.

In addition, the nanowire dispersion may contain additives or binders to control viscosity, corrosion, adhesion, and nanowire dispersion. Examples of suitable additives or binders include, but are not limited to, carboxy methyl cellulose (CMC), 2-hydroxy ethyl cellulose (HEC), hydroxy propyl methyl cellulose (HPMC), methyl cellulose (MC), poly vinyl alcohol (PVA), tripropylene gylcol (TPG), and xanthan gum (XG), and surfactants such as ethoxylates, alkoxylates, ethylene oxide and propylene oxide and their copolymers, sulfonates, sulfates, disulfonate salts, sulfosuccinates, phosphate esters, and fluorosurfactants (e.g., Zonyl® by DuPont Company, Wilmington, Del.).

In one example, a nanowire dispersion, or “ink” includes, by weight, from 0.0025% to 0.1% surfactant (e.g., a preferred range is from 0.0025% to 0.05% for Zonyl® FSO-100), from 0.02% to 4% viscosity modifier (e.g., a preferred range is 0.02% to 0.5% for HPMC), from 94.5% to 99.0% solvent and from 0.05% to 1.4% metal nanowires. Representative examples of suitable surfactants include Zonyl® FSN, Zonyl® FSO, Zonyl® FSH, Triton (×100, ×114, ×45), Dynol (604, 607), n-Dodecyl b-D-maltoside and Novek. Examples of suitable viscosity modifiers include hydroxypropyl methyl cellulose (HPMC), methyl cellulose, xanthan gum, polyvinyl alcohol, carboxy methyl cellulose, hydroxy ethyl cellulose. Examples of suitable solvents that may be present in a nanowire dispersion that includes the aforementioned binders or additives, include water and isopropanol.

If it is desired to change the concentration of the dispersion from that disclosed above, the percent of the solvent can be increased or decreased. In preferred embodiments the relative ratios of the other ingredients, however, can remain the same. In particular, the ratio of the surfactant to the viscosity modifier is preferably in the range of about 80:1 to about 0.01:1; the ratio of the viscosity modifier to the nanowires is preferably in the range of about 5:1 to about 0.000625:1; and the ratio of the nanowires to the surfactant is preferably in the range of about 560:1 to about 5:1. The ratios of components of the dispersion may be modified depending on the substrate and the method of application used. The preferred viscosity range for the nanowire dispersion is between about 1 and 1000 cP (0.001 and 1 Pa-s).

The nanowire dispersion or conductive layer is applied to the transparent energy dissipation layer or substrate at a given thickness, in an effort to achieve desirable optical and electrical properties. This application is performed using known coating methods, such as slot coating, roll coating, Mayer rod coating, dip coating, curtain coating, slide coating, knife coating, gravure coating, notch bar coating or spraying, yielding a nanowire or conductive layer on the substrate. This coating step can be performed either as a roll-to-roll process or in a piece-part fashion. Following the deposition, the liquid of the dispersion is typically removed by evaporation. The evaporation can be accelerated by heating (e.g., using a dryer). The resulting conductive layer or nanowire layer may require post-treatment to render it more electrically conductive. This post-treatment can be a process step involving exposure to heat, plasma, corona discharge, UV-ozone, or pressure as further described in PCT International Pub. No. WO 2007/02226. Optionally coating the transparent energy dissipation layer or substrate with a conductive layer or nanowire layer can be followed by hardening or curing the conductive layer or nanowire layer.

Optionally, a conductive layer or nanowire layer can be coated onto a transparent energy dissipation layer or substrate by a process wherein the layer is delivered to the substrate surface using means other than liquid dispersion coating. For example, a nanowire layer can be dry-transferred to a substrate surface from a donor substrate. As a further example, nanowires can be delivered to a transparent energy dissipation layer or substrate surface from a gas phase suspension.

In one embodiment, a layer of aqueous dispersion of nanowires (Cambrios CLEAROHM™ Ink-N-G4-02, Part Number NKA722, Lot Number 12A0014TC) may be applied to a transparent energy dissipation layer or substrate in the range 10 to 25 μm thick using a slot die coating technique. The coating formulation (e.g. % total solids by wt. and % silver nanowire solids by wt.) can be selected, along with the coating and drying process conditions, to create a nanowire layer with designed electrical and optical properties, e.g. a desired sheet resistance (Ohm/Sq) and optical properties such as transmission (%) and haze (%).

The nanowire layer that results from coating nanowires on a transparent energy dissipation layer or substrate (e.g., from a nanowire dispersion) includes nanowires and optionally binder or additives. The nanowire layer preferably includes an interconnected network of nanowires. The nanowires that make up the nanowire layer are preferably electrically connected to each other, leading approximately or effectively to a sheet conductor. The nanowire layer includes open space between the individual nanowires that make up the layer, leading to at least partial transparency (i.e., light transmission). Nanowire layers having an interconnected network of nanowires with space between the individual nanowires may be described as transparent conductor layers.

The embedded transparent conductor layer 12 may form a co-planar surface with a major surface where the embedded transparent conductor layer 12 does not extend beyond the major surface, as illustrated in FIG. 3.

The transparent conductor regions of the transparent conductor layer 12 may form linear co-extending traces or a mesh that extends on or along a substantial portion of a one or both opposing major surfaces of the transparent energy dissipation layer. The transparent conductor layer 12 or nanowires may extend along at least 75%, or at least 80% or at least 90% or at least 95% of a largest lateral distance of the transparent energy dissipation layer 14 major surface, such as the display surface. The transparent conductor layer 12 or nanowires may be configured to provide touch, position, or force sensor capability for a touch display, for example. The transparent conductor layer 12 or nanowires may be patterned onto one or both opposing major surfaces of the transparent energy dissipation layer.

FIG. 4 and FIG. 5 illustrate a conductive display film 20 having a second transparent conductor layer 22 disposed on the transparent energy dissipation layer 14 such that the transparent energy dissipation layer 14 separates the transparent conductor layers 12, 22. The second transparent conductor layer 22 may be formed of a similar material as the transparent conductor layer 12. The second transparent conductor layer 22 may include a plurality of transparent conductor regions regions extending in a direction orthogonal to the direction of the transparent conductor regions regions of the opposing transparent conductor layer 12. The second transparent conductor layer 22 may include a plurality of transparent conductor regions forming a linear extending traces or a mesh, as described above for the transparent conductor layer 12 or nanowires. The transparent conductor layers 12, 22 or transparent conductor regions regions may be configured to provide touch, position, or force sensor capability for a touch display, for example.

FIG. 6 illustrates a conductive display film 30 having a protective layer 32 disposed on the transparent energy dissipation layer 14. The protective layer 32 may provide abrasion resistance to the conductive display film 30 and may also be referred to as an abrasion resistant layer. A protective layer or abrasion resistant layer may include a hardcoat layer, a nanoparticle nanocomposite ionic elastomeric layer, an elastic nanocomposite urethane layer, or a glass layer, or siloxane based elastic composite layer.

Alternatively, conductive display film 30 includes a transparent conductor layer 12 separating the protective layer 32 from the transparent energy dissipation layer 14. A patterned transparent conductor layer 12 may not separate the protective layer 32 from the transparent energy dissipation layer 14 in the “open” or void spaces defined by the patterned regions.

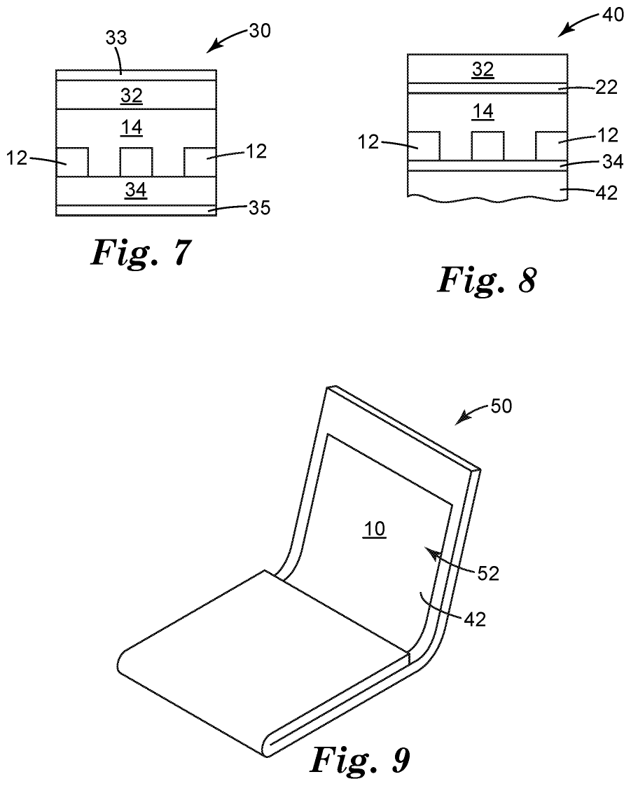

FIG. 7 illustrates a conductive display film 30 having a protective layer 32 and an adhesive layer 34 (such as an optically clear adhesive or a pressure sensitive adhesive). Release layers 33, 35 (or pre-mask layers, or release liners) may be disposed on the protective layer 32 and an adhesive layer 34 to provide protection during storage and transport of the conductive display film 30, prior to application onto a display. The release layers 33, 35 may be removed to apply the conductive display film 30 onto an optical element.

The adhesive layer 34 may adhere the conductive display film to the optical element 42 (see FIG. 8 and FIG. 9). The adhesive layer 34 may be a pressure sensitive adhesive. In some cases, the adhesive layer 34 permanently fixes the conductive display film to the optical element 42. In other cases, the conductive display film and adhesive layer 34 can be removed/debonded/repositioned, relative to the optical element 42, with the application of heat or mechanical force such that the conductive display film is replaceable or repositionable by the consumer.

The adhesive layer may be comprised of acrylate, silicone, silicone polyoxamide, silicone polyurea, polyolefin, polyester, polyurethane or polyisobutylene or mixtures thereof as long as the adhesive layer has suitable optical properties in terms of low haze, high transmission and low yellow index. In some cases, the adhesive layer may be an optically clear adhesive or a pressure sensitive adhesive. The adhesive layer may have a thickness in a range from 1 to 110 micrometers, or from 3 to 25 micrometers, or from 3 to 15 micrometers, or from 50 to 100 micrometers.

The release layers 33, 35 (or pre-mask layers) may be easily removed for application to an optical display or to reveal the conductive display film, before placement onto an optical display. The release layers 33, 35 may provide transport protection to the underlying conductive display film and optional protective layer 32 and an adhesive layer 34. The release layers 33, 35 may be layer or film that has a low surface energy to allow clean removal of the release layer or liner from the conductive display film and protective layer 32 and an adhesive layer 34. The release layers 33, 35 may be a layer of polyester coated with a silicone, for example. The release layers 33, 35 may provide temporary structure to the optional adhesive layer 34. For example, WO2014/197194 and WO2014/197368 describe removable liners that emboss a coupling layer where the adhesive layer loses its structures slowly once the removable liner is stripped away from the optical adhesive layer. This allows for ease of application where the temporary structure can allow for air bleed in lamination which then disappears in the laminated construction.

FIG. 8 illustrates a schematic diagram side elevation view of an illustrative conductive display film 20 on an optical display 42 forming an article 40. FIG. 9 is a schematic diagram perspective view of an illustrative folding article 50 including an illustrative conductive display film 10. The conductive display film 10 and the optical display 42 may be inwardly foldable (onto itself or the display surface see FIG. 9) or outwardly foldable (away from the display surfaces—not shown),

The conductive display film 10 may be any of the display film constructions described herein disposed on an optical element such as an optical display 42. The display device may not be a folding article and may only flex within a certain range, or may be a static curved display device.

An optical display 42 may form at least a portion of display device 50. The display device 50 may include a display window 52. The display device 50 can be any useful article such as a phone or smartphone, electronic tablet, electronic notebook, computer, and the like. The optical display may include an organic light emitting diode (OLED) display panel. The optical display may include a liquid crystal display (LCD) panel or a reflective display. Examples of reflective displays include electrophoretic displays, electrofluidic displays (such as an electrowetting display), interferometric displays or electronic paper display panels, and are described in US 2015/0330597.

The conductive display film 10 and the optical display 42 may be foldable so that the optical display 42 faces itself and at least a portion of conductive display film 10 contacts or directly faces another portion of the conductive display film 10, as illustrated in FIG. 9. The conductive display film 10 and the optical display 42 may be flexible or bendable or foldable so that a portion of the conductive display film 10 and the optical display 42 can articulate relative to another portion of the conductive display film 10 and the optical display 42. The display film 10 and the optical display 42 may be flexible or bendable or foldable so that a portion of the conductive display film 10 and the optical display 42 can articulate at least 90 degrees or at least 170 degrees relative to another portion of the conductive display film 10 and the optical display 42.

The conductive display film 10 and the optical display 42 may be flexible or bendable or foldable so that a portion of the conductive display film 10 and the optical display 42 can articulate relative to another portion of the conductive display film 10 and optical display 42 to form a bend radius of 3 mm or less in the conductive display film 10 at the bend or fold line. The conductive display film 10 and the optical display 42 may be flexible or bendable or foldable so that a portion of the conductive display film 10 and optical display 42 can articulate relative to another portion of the conductive display film 10 and the optical display 42 to form a bend radius such that the conductive display film 10 overlaps itself and is separated from each other by a distance on 10 mm or less, or 6 mm or less or 3 mm or less or contacts each other.

The conductive display films described herein may have a haze value of less than 5%, or less than 3%, or 2% or less, or 1.5% or less, or 1% or less, or 0.5% or less. The conductive display film may have a clarity of 90% or greater, or 95% or greater, or 98% or greater, or 99% or greater. The conductive display film may have a visible light transmission of 85% or greater, or 90% or greater, or 93% or greater. The conductive display film may have a yellow index or b* value of 5 or less, or 4 or less, or 3 or less, or 2 or less, or 1 or less. In many embodiments, the conductive display film may have a yellow index or b* value of 1 or less.

The transparent energy dissipation layer 14 may have a uniform thickness. The transparent energy dissipation layer 14 may have a thickness (along the y-axis) in a range from 20 to 250 micrometers, or from 25 to 200 micrometers, or from 25 to 150 micrometers, or from 50 to 100 micrometers, or from 50 to 250 micrometers, or from 100 to 200 micrometers, or from 125 to 200 micrometers, or from 150 to 200 micrometers. The thickness of the transparent energy dissipation layer is a balance between being thick enough to provide the desired protection to the conductive display and thin enough to provide the folding and reduced thickness design parameters.

The one or both transparent conductor layers 12, 22 may be embedded within the one major surface or both opposing major surfaces of the transparent energy dissipation layer 14. A portion of the transparent energy dissipation layer 14 separates adjacent nanowires (or nanowire regions) from each other when the one or both transparent conductor layers 12, 22 are embedded within the one major surface or both opposing major surfaces of the transparent energy dissipation layer 14. The embedded transparent conductor layers 12, 22 may form a co-planar surface with one or both of the opposing major surfaces of the transparent energy dissipation layer 14.

The transparent energy dissipation layer 14 may have a glass transition temperature of 45 degrees Celsius or less, 40 degrees Celsius or less, 35 degrees Celsius or less, 30 degrees Celsius or less, 27 degrees Celsius or less, 25 degrees Celsius or less, 20 degrees Celsius or less, 15 degrees Celsius or less, 10 degrees Celsius or less, 5 degrees Celsius or less, or 0 degrees Celsius or less, or −5 degrees Celsius or less, or in a range from −40 to 15 degrees Celsius, or in a range from −30 to 15 degrees Celsius, or in a range from −30 to 10 degrees Celsius, or in a range from −30 to 5 degrees Celsius, or in a range from −30 to 0 degrees Celsius, or in a range from −20 to 0 degrees Celsius.

The transparent energy dissipation layer 14 may have a Tan Delta peak value of 0.5 or greater, or 0.8 or greater, or 1.0 or greater, or 1.2 or greater, or from 0.5 to 2.5, or from 1 to 2.5, or from 1 to 2. The energy dissipation layer or layers have a Young's Modulus (E′) greater than 0.9 MPa over the temperature range −40 degrees Celsius to 70 degrees Celsius. The energy dissipation layer would not be referred to as a pressure sensitive adhesive.

The transparent energy dissipation layer 14 may be formed of a plurality of layers, and at least two of these layers having a different glass transition temperature value. These layers may have a different glass transition temperature value by at least 2 degrees Celsius, or at least 5 degrees Celsius, or at least 10 degrees Celsius, for example. In some cases, each energy dissipation layer peak Tan Delta values may occur at different frequencies at a specified temperature.

The transparent energy dissipation layer 14 may be formed of a cross-linked polyurethane, or cross-linked polyurethane acrylate, or cross-linked polyurethane and polyacrylate. The transparent energy dissipation layer 14 may demonstrate shape-memory, in that when deformed it will recover to its original shape.

The transparent energy dissipation layer may be formed with a transparent cross-linked polyurethane layer. The transparent cross-linked polyurethane layer preferably includes chemically or covalently crosslinked materials derived from step growth polymerization of isocyanate and polyol oligomers. Selection of reactant isocyanates and polyols may modify the glass transition temperature of the resulting cured polyurethane. The cross-linked polyurethane layer may be coated onto a transparent substrate or glass layer (that may be primed) and then be cured or cross-linked to form a thermoset polyurethane layer. Alternatively, the cross-linked polyurethane layer could be produced as a film that is then laminated to a substrate or glass layer in a subsequent process step. Such lamination could be assisted with heat, vacuum, or through the use of an adhesive or combination thereof.

Polyurethane is a polymer composed of organic units joined by carbamate (urethane) links. The polyurethanes described herein are thermosetting polymers that do not melt when heated. Polyurethane polymers may be formed by reacting a di- or polyisocyanate with a polyol. Both the isocyanates and polyols used to make polyurethanes contain on average two or more functional groups per molecule. The polyurethanes described herein may have a functionality greater than 2.4 or 2.5.

A wide variety of polyols may be used to form the aliphatic cross-linked polyurethane component of the transparent energy dissipation layer. The term polyol includes hydroxyl-functional materials that generally include at least 2 terminal hydroxyl groups. Polyols include diols (materials with 2 terminal hydroxyl groups) and higher polyols such as triols (materials with 3 terminal hydroxyl groups), tetraols (materials with 4 terminal hydroxyl groups), and the like. Typically the reaction mixture contains at least some diol and may also contain higher polyols. Higher polyols are particularly useful for forming crosslinked polyurethane polymers. Diols may be generally described by the structure HO—B—OH, where the B group may be an aliphatic group, an aromatic group, or a group containing a combination of aromatic and aliphatic groups, and may contain a variety of linkages or functional groups, including additional terminal hydroxyl groups.

Polyester polyols are particularly useful. Among the useful polyester polyols useful are linear and non-linear polyester polyols including, for example, polyethylene adipate, polybutylene succinate, polyhexamethylene sebacate, polyhexamethylene dodecanedioate, polyneopentyl adipate, polypropylene adipate, polycyclohexanedimethyl adipate, and poly ε-caprolactone. Particularly useful are aliphatic polyester polyols available from King Industries, Norwalk, Conn., under the trade name “K-FLEX” such as K-FLEX 188 or K-FLEX A308.

A wide variety of polyisocyanates may be used to form the aliphatic cross-linked polyurethane component of the transparent energy dissipation layer. The term polyisocyanate includes isocyanate-functional materials that generally include at least 2 terminal isocyanate groups. Polyisocyanates include diisocyanates (materials with 2 terminal isocyanate groups) and higher polyisocyanates such as triisocyanates (materials with 3 terminal isocyanate groups), tetraisocyanates (materials with 4 terminal isocyanate groups), and the like. Typically the reaction mixture contains at least one higher isocyanate if a difunctional polyol is used. Higher isocyanates are particularly useful for forming crosslinked polyurethane polymers. Diisocyanates may be generally described by the structure OCN—Z—NCO, where the Z group may be an aliphatic group, an aromatic group, or a group containing a combination of aromatic and aliphatic groups.

Higher functional polyisocyanates are particularly useful, such as triisocyanates, to form a crosslinked polyurethane polymer. Triisocyanates include, but are not limited to, polyfunctional isocyanates, such as those produced from biurets, isocyanurates, adducts, and the like. Some commercially available polyisocyanates include portions of the DESMODUR and MONDUR series from Bayer Corporation, Pittsburgh, Pa., and the PAPI series from Dow Plastics, a business group of the Dow Chemical Company, Midland, Mich. Particularly useful triisocyanates include those available from Bayer Corporation under the trade designations DESMODUR N3300A and MONDUR 489. One particularly suitable aliphatic polyisocyanate is DESMODUR N3300A.

The reactive mixture used to form the transparent aliphatic cross-linked polyurethane component of the transparent energy dissipation layer also contains a catalyst. The catalyst facilitates the step-growth reaction between the polyol and the polyisocyanate. Conventional catalysts generally recognized for use in the polymerization of urethanes may be suitable for use with the present disclosure. For example, aluminum-based, bismuth-based, tin-based, vanadium-based, zinc-based, or zirconium-based catalysts may be used. Tin-based catalysts are particularly useful. Tin-based catalysts have been found to significantly reduce the amount of outgassing present in the polyurethane. Most desirable are dibutyltin compounds, such as dibutyltin diacetate, dibutyltin dilaurate, dibutyltin diacetylacetonate, dibutyltin dimercaptide, dibutyltin dioctoate, dibutyltin dimaleate, dibutyltin acetonylacetonate, and dibutyltin oxide. In particular, the dibutyltin dilaurate catalyst DABCO T-12, commercially available from Air Products and Chemicals, Inc., Allentown, Pa. is particularly suitable. The catalyst is generally included at levels of at least 200 ppm or even 300 ppm or greater. The catalyst may be present in the final formed films at levels of at least 100 ppm or in a range from 100-500 ppm.

The cross-linked polyurethane fraction of the energy dissipation layer may have a cross-link density in a range from 0.1 to 1.0 mol/kg or from 0.2 to 0.9 mol/kg or from 0.37 to 0.74 mol/kg. The crosslink density of the cured polyurethane is calculated using the method described in Macromolecules, Vol. 9, No. 2, pages 206-211 (1976). To implement this model, integral values for chemical functionality are required. DESMODUR N3300 is reported to have an average functionality of 3.5 and an isocyanate equivalent weight of 193 g/equiv. This material was represented in the mathematical model as a mixture of 47.5 wt % HDI trimer (168.2 g/equiv.), 25.0 wt % HDI tetramer (210.2 g/equiv.), and 27.5 wt % of HDI pentamer (235.5 g/equiv.). This mixture yields an average equivalent weight of 193 g/equiv. and an average functionality of 3.5. Desmodur N3400 is reported to have an average functionality 2.5 and an equivalent weight of 193, and it is reported to be blend of the HDI isocyanurate trimer and HDI uretdione dimer. This material was represented in the mathematical model as a mixture of 19 wt % HDI isocyanurate trimer, 33 wt % HDI uretdione dimer, and 10 wt % of HDI uretdione trimer and 38 wt % of HDI tetramer having one isocyanurate group and one uretdione group. In the mathematical model, the functionality was determined by the sum the isocyanate groups and the uretdione groups in the cases where there was an excess of hydroxyl groups relative to the sum of the isocyanate and uretdione groups.

To produce an energy dissipation layer with a glass transition temperature below 10° C., it can be preferable to limit the amount of the isocyanate component. In some embodiments using HDI-derived isocyanates, it can be preferable to use less than 40 wt % isocyanate component based on the total core layer composition, or less than 38 wt %, or less than 35 wt %. In some embodiments, it is preferable to use an isocyanate component containing uretdione groups. When uretdione groups are included, it can be preferable to use an excess of hydroxyl functional groups relative to isocyanate groups. The excess hydroxyl groups can react with the uretdione groups to form allophanate groups to provide cure and chemical crosslinking. In some embodiments, it is preferable to include only a single polyol component to produce a narrow tan delta peak. In some embodiments, it is preferable to use a polyol component and an isocyanate component that are miscible with each other at room temperature.

The transparent energy dissipation layer may be formed with urethane acrylate oligomers. Urethane acrylate oligomers may be comprised of a wide variety of urethane materials with acrylate or methacrylate reactive groups. Urethane acrylate oligomers are commercially available from vendors such as, for example, Sartomer of Exton, Pa. (a subsidiary of Arkema) and Allnex (Ebecryl Brand name).

Examples of commercially available aliphatic urethane oligomers include but are not limited to CN9002, CN9004, CN9893, and CN3211 available from Sartomer Company and those sold under the Ebecryl brand name.

The transparent energy dissipation layer may be formed by mixing the polyurethane precursor components with polyacrylate precursor components. The polyurethane and the polyacrylate polymers are formed via distinct initiators. This allows the polyacrylate polymer to be selectively formed without forming the polyurethane polymer. The polyurethane polymer may be formed with the use of a catalyst (thermal curing) and the polyacrylate may be formed with the use of a photoinitator (UV or light curing), for example.

The transparent energy dissipation layer precursor (containing both the polyurethane precursor components with the polyacrylate precursor components with both photoinitiator and catalyst) may be coated onto the transparent polymeric substrate layer (that may be primed) or the glass layer and then the polyacrylate polymer may be selectively polymerized or cross-linked (via UV curing) to form a b-stage layer. Then this b-stage layer can be cured or cross-linked to form the thermoset or cross-linked polyurethane polymer and complete the formation of the transparent energy dissipation layer.

The transparent energy dissipation layer may contain from 1 to 50% wt polyacrylate polymer. The transparent energy dissipation layer may contain from 50 to 99% wt cross-linked polyurethane polymer. The transparent energy dissipation layer may contain from 1 to 20% wt polyacryate polymer. The transparent energy dissipation layer may contain from 2 to 15% wt polyacryate polymer. The transparent energy dissipation layer may contain from 3 to 10% wt polyacryate polymer. The transparent energy dissipation layer may contain from 80 to 99% wt cross-linked polyurethane polymer. The transparent energy dissipation layer may contain from 85 to 98% wt cross-linked polyurethane polymer. The transparent energy dissipation layer may contain from 90 to 97% wt cross-linked polyurethane polymer. The transparent energy dissipation layer may contain both a photoinitiator and a catalyst.

When the transparent energy dissipation layer contains less than about 10% wt polyacrylate (based on wt % of polyacrylate precursor material in the precursor mixture), it is believed that the polyacrylate defines a mainly a linear or branched polymer. When the transparent energy dissipation layer contains about 10% wt to about 20% wt polyacrylate (based on wt % of polyacrylate precursor material in the precursor mixture), it is believed that the polyacrylate defines a branched or cross-linked polymer. When the transparent energy dissipation layer contains about 20% wt to about 50% wt polyacrylate (based on wt % of polyacrylate precursor material in the precursor mixture), it is believed that the polyacrylate defines mainly a cross-linked polymer. Cross-linked polyacrylate may define an interpenetrating network with the cross-linked polyurethane in the transparent energy dissipation layer.

The polyacrylate polymer is polymerized or cross-linked. The polyacrylate polymer may be formed of acrylate monomers or oligomers. In some embodiments, the polyacrylate is a polyacrylate homopolymer. The acrylate monomers or oligomers are multifunctional to enable polymerization or cross-linking of the polyacrylate polymer. The polyacrylate polymer may be formed with the aid of an initiator, such as a photo-initiator, for example. The polyacrylate polymer may be formed of oligomers that include acrylate and urethane segments, or acrylate and urethane compatible segments. The polyacrylate polymer may be aliphatic.

The polyacrylate polymer may be formed of multifunctional (meth)acrylic monomers, oligomers, and polymers, where the individual resins can be difunctional, trifunctional, tetrafunctional or higher functionality. Useful multifunctional acrylate monomers and oligomers include:
(a) di(meth)acryl containing monomers such as 1,3-butylene glycol diacrylate, 1,4-butanediol diacrylate, 1,6-hexanediol diacrylate, 1,6-hexanediol monoacrylate monomethacrylate, ethylene glycol diacrylate, alkoxylated aliphatic diacrylate, alkoxylated cyclohexane dimethanol diacrylate, alkoxylated hexanediol diacrylate, alkoxylated neopentyl glycol diacrylate, caprolactone modified neopentylglycol hydroxypivalate diacrylate, caprolactone modified neopentylglycol hydroxypivalate diacrylate, cyclohexanedimethanol diacrylate, diethylene glycol diacrylate, dipropylene glycol diacrylate, ethoxylated bisphenol A diacrylate, hydroxypivalaldehyde modified trimethylolpropane diacrylate, neopentyl glycol diacrylate, polyethylene glycol diacrylate, propoxylated neopentyl glycol diacrylate, tetraethylene glycol diacrylate, tricyclodecanedimethanol diacrylate, triethylene glycol diacrylate, tripropylene glycol diacrylate;
(b) tri(meth)acryl containing monomers such as glycerol triacrylate, trimethylolpropane triacrylate, ethoxylated triacrylates (e.g., ethoxylated trimethylolpropane triacrylate), propoxylated triacrylates (e.g., propoxylated glyceryl triacrylate, propoxylated trimethylolpropane triacrylate), trimethylolpropane triacrylate, tris(2-hydroxyethyl)isocyanurate triacrylate;
(c) higher functionality (meth)acryl containing monomer such as ditrimethylolpropane tetraacrylate, dipentaerythritol pentaacrylate, pentaerythritol triacrylate, ethoxylated pentaerythritol tetraacrylate, and caprolactone modified dipentaerythritol hexaacrylate.

Oligomeric (meth)acryl monomers such as, for example, urethane acrylates may also be employed.

Such (meth)acrylate monomers are widely available from vendors such as, for example, Sartomer Company of Exton, Pa.; Cytec Industries of Woodland Park, N.J.; and Aldrich Chemical Company of Milwaukee, Wis.

In some embodiments, the polyacrylate polymer includes a (meth)acrylate monomer comprising at least three (meth)acrylate functional groups. In some embodiments, the crosslinking monomer comprises at least four, five or six (meth)acrylate functional groups. Acrylate functional groups may be favored over (meth)acrylate functional groups.

Preferred functional acrylates include for example trimethylolpropane triacrylate (commercially available from Sartomer Company, Exton, Pa. under the trade designation “SR351”), ethoxylated trimethylolpropane triacrylate (commercially available from Sartomer Company, Exton, Pa. under the trade designation “SR454”), pentaerythritol tetraacrylate, pentaerythritol triacrylate (commercially available from Sartomer under the trade designation “SR444”), dipentaerythritol pentaacrylate (commercially available from Sartomer under the trade designation “SR399”), ethoxylated pentaerythritol tetraacrylate (from Sartomer under the trade designation “SR494”), dipentaerythritol hexaacrylate, and tris(2-hydroxy ethyl) isocyanurate triacrylate (from Sartomer under the trade designation “SR368”.

Aliphatic urethane acrylate oligomers may be utilized to form a preferred polyacrylate polymer to enhance compatibility of the polyacrylate polymer and the cross-linked polyurethane, although other aliphatic polyacrylate monomers may also be useful. The polyacrylates or polyurethane acrylates described herein are thermosetting polymers.

The polyacrylate polymer may be formed by free radical polymerization of multifunctional urethane acrylate oligomers. The urethane acrylate oligomer may be mixed with other low molecular weight monofunctional and/or multifunctional acrylates to modify the pre-cured viscosity of the resin for the purposes of processing. Generally the average functionality of the multifunctional acrylate used in the energy dissipation layer prior to cure is less than 3 (i.e. 3 functional acrylate functional groups per molecule) or can be 2 or less. The cured (or crosslinked) material may exhibit stable material properties with respect to the display film use in application, that is, the energy dissipation layer may not exhibit appreciable flow.

The conductive display film may include a protective layer 32. The protective layer may provide abrasion resistance to the display film and may also be referred to as an abrasion resistant layer. A protective layer or abrasion resistant layer includes a hardcoat layer, a nanoparticle nanocomposite ionic elastomeric layer, an elastic nanocomposite urethane layer, or a glass layer.

Abrasion is a method of wearing down or rubbing away material by means of friction. The abrasion resistance of a material helps it to withstand mechanical action and tends to protect the removal of materials from its surface. This allows the material to retain its integrity and hold its form. Abrasion resistance can be measured by rubbing or wiping the transparent protective layer for a specified number of cycles with a rough material such as steel wool or a scouring pad and then inspecting the layer for visible changes such as fine scratches or haze.

The protective layer or abrasion resistant layer may include a hardcoat layer disposed directly on a conductive display film layer (for example on the energy dissipation layer) or the hardcoat layer may be formed on a substrate layer that is fixed to the energy dissipation layer. The hardcoat layer (without the substrate layer) may have a thickness of less than 50 micrometers, or less than 40 micrometers, or a thickness in a range from 2 to 30 micrometers, or from 2 to 15 micrometers, or from 3 to 10 micrometers. The hardcoat layer may be disposed on a polymeric substrate layer such as polymethylmethacrylate, polycarbonate, polyamide, polyimide (preferably colorless polyimide), polyester (PET, PEN), polycyclic olefin polymer, or thermoplastic polyurethane.

The hardcoat layer may include nanoparticles. Suitable hardcoats can include a variety of cured polymeric materials having inorganic nanoparticles. These hardcoats can include but are not limited to (meth)acrylic based hardcoats, siloxane hardcoats, polyurethane hardcoats and the like.

One preferable class of hardcoats includes acrylic hardcoats comprising inorganic nanoparticles. Such hardcoats can have a polymerizable resin composition comprising mixtures of multifunctional (meth)acrylic monomers, oligomers, and polymers, where the individual resins can be monofunctional, difunctional, trifunctional, tetrafunctional or have even higher functionality. In preferred cases, the polymerizable (meth)acrylate components of the resin system are chosen such that when polymerized the hardcoat contains little to no free (meth)acrylic monomers.

Such (meth)acrylate monomers are widely available from vendors such as, for example, Sartomer Company of Exton, Pa.; Cytec Industries of Woodland Park, N.J.; and Aldrich Chemical Company of Milwaukee, Wis.

The hardcoat composition may include surface modified inorganic oxide particles that add mechanical strength and durability to the resultant coating. The particles are typically substantially spherical in shape and relatively uniform in size. The particles can have a substantially monodisperse size distribution or a polymodal distribution obtained by blending two or more substantially monodisperse distributions. The inorganic oxide particles are typically non-aggregated (substantially discrete), as aggregation can result in precipitation of the inorganic oxide particles or gelation of the hardcoat. The size of inorganic oxide particles is chosen to avoid significant visible light scattering.

The hardcoat composition may include a significant amount of surface modified inorganic oxide nanoparticles having an average (e.g. unassociated) primary particle size or associated particle size of at least 10, 20, 30, 40 or 50 nm and no greater than about 200, 175 or 150 nm. When the hardcoat composition lacks a significant amount of inorganic nanoparticles of such size, the cured hardcoat can crack when subjected to the pencil hardness test. Inorganic nonparticles may be beneficial to managing cure shrinkage while maintaining optical properties. The total concentration of inorganic oxide nanoparticles is typically a least 30, 35, or 40 wt-% solids and generally no greater than 90 wt-%, 80 wt-%, or 75 wt-% and in some embodiments no greater than 70 wt-%, or 65 wt-%, or 60 wt-% solids.

The hardcoat composition may comprise up to about 10 wt-% solids of smaller nanoparticles. Such inorganic oxide nanoparticles typically having an average (e.g. unassociated) primary particle size or associated particle size of at least 1 nm or 5 nm and no greater than 50, 40, or 30 nm.

Aqueous colloidal silicas dispersions are commercially available from Nalco Chemical Co., Naperville, Ill. under the trade designation “Nalco Collodial Silicas” such as products 1040, 1042, 1050, 1060, 2327, 2329, and 2329K or Nissan Chemical America Corporation, Houston, Tex. under the trade name Snowtex™. Organic dispersions of colloidal silicas are commercially available from Nissan Chemical under the trade name Organosilicasol™. Suitable fumed silicas include for example, products commercially available from Evonki DeGussa Corp., (Parsippany, N.J.) under the trade designation, “Aerosil series OX-50”, as well as product numbers -130, -150, and -200. Fumed silicas are also commercially available from Cabot Corp., Tuscola, Ill., under the trade designations CAB-O-SPERSE 2095”, “CAB-O-SPERSE A105”, and “CAB-O-SIL M5”.

It may be desirable to employ a mixture of inorganic oxide particle types to optimize an optical property, material property, or to lower that total composition cost.

As an alternative to or in combination with silica the hardcoat may comprise various high refractive index inorganic nanoparticles. Such nanoparticles have a refractive index of at least 1.60, 1.65, 1.70, 1.75, 1.80, 1.85, 1.90, 1.95, 2.00 or higher. High refractive index inorganic nanoparticles include for example zirconia (“ZrO₂”), titania (“TiO₂”), antimony oxides, alumina, tin oxides, alone or in combination. Mixed metal oxide may also be employed.

Zirconias for use in the hardcoat layer are available from Nalco Chemical Co. under the trade designation “Nalco OOSS008”, Buhler AG Uzwil, Switzerland under the trade designation “Buhler zirconia Z-WO sol” and Nissan Chemical America Corporation under the trade name NanoUse ZR™. Zirconia nanoparticles can also be prepared such as described in U.S. Patent Publication No. 2006/0148950 and U.S. Pat. No. 6,376,590. A nanoparticle dispersion that comprises a mixture of tin oxide and zirconia covered by antimony oxide (RI-1.9) is commercially available from Nissan Chemical America Corporation under the trade designation “HX-05M5”. A tin oxide nanoparticle dispersion (RI 2.0) is commercially available from Nissan Chemicals Corp. under the trade designation “CX-S401M”. Zirconia nanoparticles can also be prepared such as described in U.S. Pat. Nos. 7,241,437 and 6,376,590.

The protective layer may be an elastic nanocomposite layer. The elastic nanocomposite layer may be a nanoparticle nanocomposite ionic elastomeric layer, or an elastic nanocomposite urethane layer. The nanoparticle nanocomposite ionic elastomeric layer, or the elastic nanocomposite urethane layer may be directly coated onto the transparent energy dissipation layer or adhesive layer or substrate layer. Alternatively, the nanoparticle nanocomposite ionic elastomeric layer, or the elastic nanocomposite urethane layer may be coated onto a transparent substrate layer, as described above, and the transparent substrate layer is directly attached to the transparent energy dissipation layer or adhesive layer.

The protective layer may be an elastic nanocomposite layer. This layer may have a thickness in a range from 30 to 125 micrometers. This elastic nanocomposite material can be made from any useful material that provides durable surface properties to the outer layer. In some cases, this elastic nanocomposite layer is made from polyurethane nanocomposite materials such as silica nanoparticle filled UV curable polyurethane resins. In other embodiments, the elastic nanocomposite material can be made from nanoparticle filled ionic elastomer materials. This elastic nano-composite layer is capable of stretching within an elastic range, so that permanent deformation does not occur. The proportional limit for a material is defined as the maximum stress at which the stress is proportional to strain (Hooke's law). The elastic limit is the minimum stress at which permanent deformation can be measured. The elastic nano-composite layer may have a strain at the elastic limit that is 20% greater than the strain at the proportional limit, 50% greater than the strain at the proportional limit, or 100% greater than the strain at the proportional limit.

The protective layer may be a thin glass layer having a thickness in a range from 15 to 500 micrometers, or from 20 to 120 micrometers, or from 30 to 100 micrometers, or from 30 to 80 micrometers. An intermediate adhesive layer may fix the protective layer or glass layer to the transparent energy dissipation layer. The intermediate adhesive layer mechanically and optically couples the protective or glass layer to the energy dissipation layer. The intermediate adhesive layer may have a thickness in a range from 1 to 100 micrometers, or from 5 to 75 micrometers, or 10 to 70 micrometers, or from 20 to 55 micrometers.

The illustrative conductive display film constructions described herein may include an ink border that defines a viewing window. The ink border may be a continuous frame element printed, for example, onto the transparent glass layer or the energy dissipation layer, for example.

The conductive display films described herein may include one or more additional layers. Additional layers may include barrier layers. One or more additional transparent polymeric substrate layers may be disposed in the conductive display film of any useful polymeric material that provides desired mechanical properties (such as dimensional stability) and optical properties (such as light transmission and clarity) to the conductive display film. Examples of materials suitable for use in the polymeric substrate layer include polymethylmethacrylate, polycarbonate, polyamides, polyimide, polyesters (PET, PEN), polycyclic olefin polymers, and thermoplastic polyurethanes.

The optional one or more barrier layers may include a transparent barrier layer. The transparent barrier layer may be disposed on the protective layer (when present) or the energy dissipation layer. The transparent barrier layer can mitigate or slow ingress of oxygen or water through the conductive display film. Transparent barrier layers may include for example, thin alternating layers of silica, alumina or zirconia together with an organic resin. Exemplary transparent barrier layer are described in U.S. Pat. No. 7,980,910 and WO2003/094256.

Optional additional layers may include a microstructure layer, an anti-glare layer, anti-reflective layer, or an anti-fingerprint layer. Additional optional layers may be disposed in the interior of the conductive display film. One useful additional layer disposed within the conductive display film is a sparkle reduction layer as described in WO2015/191949. The sparkle reduction layer may be particularly useful with high definition displays that include anti-glare coatings.

The conductive display film may have a thickness of less than 500 micrometers, or less than 300 micrometers, or less than 200 micrometers, or in a range from 85 to 350 micrometers or from 100 to 250 micrometers or from 100 to 200 micrometers.

Objects and advantages of this disclosure are further illustrated by the following examples, but the particular materials and amounts thereof recited in these examples, as well as other conditions and details, should not be construed to unduly limit this disclosure.

### EXAMPLES

All parts, percentages, ratios, etc. in the examples are by weight, unless noted otherwise. Solvents and other reagents used were obtained from Sigma-Aldrich Corp., St. Louis, Mo. unless specified differently.

TABLE 1
Materials

| Abbreviation or Trade | |
|---|---|
| Designation | Description |
| K-FLEX 188 | Aliphatic polyester polyol, commercially available from King Industries, |
| “Polyol 1” | Norwalk, CT under the trade name “K-FLEX 188” |
| Fomrez 55-112 | Hydroxyl terminated saturated linear polyester available from Chemtura, |
| “Polyol 2” | Middlebury, CT under the trade name “Fomrez 55-112” |
| DESMODUR N3300A | Aliphatic polyisocyanate, commercially available from Bayer, Pittsburgh, PA |
| | under the trade name “DESMODUR N3300A”. |
| DESMODUR N3400 | Aliphatic polyisocyanate, commercially available from Bayer, Pittsburgh, PA |
| | under the trade name “DESMODUR N3400”. |
| DABCO T-12 | Dibutyltin dilaurate catalyst, commercially available from Air Products and |
| | Chemicals, Inc., Allentown, PA, under the trade name “DABCO T-12”. |
| CN9004 | Aliphatic polyurethane acrylate oligomer, commercially available from |
| | Sartomer Arkema Group, Exton, PA. |
| CN3211 | Aliphatic polyester polyurethane acrylate oligomer, commercially available |
| | from Sartomer Arkema Group, Exton, PA. |
| CD9043 | Alkoxylated neopentyl glycol diacrylate, commercially available from |
| | Sartomer Arkema Group, Exton, PA. |
| SR501 | Propoxylated trimethylolpropane triacrylate, commercially available from |
| | Sartomer Arkema Group, Exton, PA. |
| SR531 | Cyclic trimethylol formal acrylate, commercially available from the |
| | Sartomer Arkema Group, Exton, PA. |
| SR415 | Ethoxylated trimethylolpropane triacrylate, commercially available from the |
| | Sartomer Arkema Group, Exton, PA. |
| Irgacure TPO-L | Liquid photinitiator, BASF |
| Irgacure 184 | Photoinitiator, BASF |
| CLEARROHM | 1% silver nanowire aqueous solution, commercially available from Cambrios |
| Generation 5 | Technologies Corp., Sunnyvale, CA. |
| PFI-722 Silver Ink | 1.5% Silver nanowire ink, commercially available from NovaCentrix., |
| | Austin, TX. |

### Polyurethane Examples 1-5

Samples of shape memory or energy dissipation polyurethane were prepared in a roll to roll process where the isocyanate and polyol with catalyst were mixed using an inline dynamic mixer. The solutions were applied to a moving web between two silicone release liners at an appropriate flow rate to achieve the desired final sample thickness. The polyurethane between films were heated at 70° C. and wound into a roll. The films were postbaked at 70° C. for 24 hours prior to lamination to glass. Samples had a range of equivalents of NCO reacted with 1.0 equivalents of —OH, as shown in Table 2 in order to achieve the desired glass transition temperature and crosslink concentration. Relative proportions by mass of K-FLEX 188 and Desmodur N3300 for samples 1-5 are shown in Table 2. The coated materials contained about 350 ppm dibutyltin dilaurate catalyst.

TABLE 2
Coating compositions and theoretical crosslink concentration

| | | | | | Theoretical |
|---|---|---|---|---|---|
| | Polyol with | DESMODUR | | Theoretical | Crosslink |
| | catalyst | 3300 | NCO/OH | Gel | Concentration |
| Example | (g) | (g) | Ratio | Content | (mol/kg) |
| 1 | 32.8 | 20.74 | 0.8 | 96.67% | 0.34 |
| 2 | 32.8 | 22.03 | 0.85 | 98.31% | 0.42 |
| 3 | 32.8 | 23.33 | 0.9 | 99.32% | 0.49 |
| 4 | 32.8 | 24.62 | 0.95 | 99.85% | 0.57 |
| 5 | 32.8 | 25.92 | 1 | 100% | 0.65 |

### Polyurethane Examples 6-9

Similar to samples 1-5, but these polyurethane coatings were made with a mixture of isocyanates. The polyurethanes, for these examples, was composed of an aliphatic polyol (K-FLEX 188) reacted with a blend of multifunctional isocyanates (Desmodur N3300 and Desmodur N3400), prepared in the same manner as samples 1-5. The weight ratio K-FLEX to Desmodur N3300 to Desmodur N3400 for samples 6-9 are shown in Table 3.

TABLE 3
Mix ratios for polyurethanes for Examples 6-9

| | | | | | | Theoretical | Theoretical |
|---|---|---|---|---|---|---|---|
| | | | | NCO/OH | (NCO + UD)/OH | Gel | Crosslink |
| Example | K188 | N3300 | N3400 | Ratio | Ratio¹ | Content | Concentration |
| 6 | 62.8 | 0 | 37.2 | 0.75 | 1.03 | 100% | 0.74 |
| 7 | 62.4 | 18.8 | 18.8 | 0.76 | 0.91 | 99.3% | 0.55 |
| 8 | 65.2 | 17.4 | 17.4 | 0.67 | 0.80 | 96.5% | 0.37 |
| 9 | 62.5 | 25.0 | 12.5 | 0.76 | 0.85 | 98.3% | 0.45 |

¹Note that the N3400 isocyanate contains a uretdione unit that can react with excess OH in the polyol component at elevated temperature to form an allophanate group. For this reason, the table contains two stoichiometric ratio columns. The first calculates the NCO/OH ratio based on only existing NCO content in N3300 and N3400 at the beginning of the reaction. The NCO + UD/OH ratio accounts for the ratio after the uretdione is reacted with excess OH of the polyol.

### Polyurethane Example 10

Similar to samples 1-5, but this polyurethane coating was made with an alternative polyol, Fomrez 55-112 in order to achieve an even lower glass transition temperature. The polyurethane was composed of an aliphatic polyol (Fomrez 55-112) reacted with a multifunctional isocyanate (Desmodur N3300), prepared in the same manner as samples 1-5. The weight ratio Fomrez 55-112 to Desmodur N3300 for sample 10 is shown in Table 4. Ovens were run at 70° C. and the samples were post-cured for 24 hours at 70° C.

TABLE 4
Coating composition and theoretical crosslink concentration

| | | | | | Theoretical |
|---|---|---|---|---|---|
| | Fomrez 55-112 | DESMODUR | | Theoretical | Crosslink |
| | with catalyst | 3300 | NCO/OH | Gel | Concentration |
| Example | (g) | (g) | Ratio | Content | (mol/kg) |
| 10 | 72.0 | 28.05 | 1.00 | 100.0% | 0.41 |

Polyurethane Layer Characterization

Glass Transition Temperature

The glass transition temperature of the polyurethane coatings was characterized using Q800 DMA from TA Instruments. Samples were cut into strips 6.35 mm wide and about 4 cm long. The thickness of each film was measured. The films were mounted in the tensile grips of a Q800 DMA from TA Instruments with an initial grip separation between 16 mm and 19 mm. The samples were then tested at an oscillation of 0.2% strain and 1 Hz throughout a temperature ramp from −50° C. to 200° C. at a rate of 2° C. per minute. The results are shown in Table 5. The onset of the glass transition was determined by location of peak for E″. The temperature at which the Tan Delta signal reached a maximum was recorded as the peak Tan Delta temperature.

TABLE 5
Thermal and mechanical properties of the coatings alone

| | Dynamic Mechanical Analysis | | | |
|---|---|---|---|---|
| | | Storage | | Temp at peak |
| | Tg by E″ | Modulus @ °0 C. | Peak Tan | Tan Delta |
| Example | (° C.) | (GPa) | Delta | (° C.) |
| 1 | 25.2 | 1.47 | 1.79 | 39.4 |
| 2 | 30.9 | 1.47 | 1.66 | 43.9 |
| 3 | 37.5 | 1.4 | 1.68 | 47.5 |
| 4 | 40.8 | 1.43 | 1.61 | 49.8 |
| 5 | 38.6 | 1.54 | 1.46 | 47.5 |
| 6 | 9.32 | 1.36 | 1.76 | 16.1 |
| 7 | 13.5 | 1.62 | 1.76 | 25.6 |
| 8 | 8.7 | 1.54 | 1.87 | 20.5 |
| 9 | 6.2 | 1.75 | 1.48 | 18.5 |
| 10 | −25 | 0.003 | 1.32 | −11 |

### Example 11

### Polyurethane Acrylate Resin and Film

Into a Flacktek Inc. size 20 speedmixer cup was added 99.5 g of CN9004 and 0.5 g of Irgacure TPO-L catalyst. The contents were mixed using a Flacktek DAC 150 FVZ-K speedmixer and were mixed at 3100 rpm for 1 min. The resulting solution was homogeneous near colorless viscous solution. The resulting solution was then placed into a vacuum oven at 40 Celsius and was degassed to remove all dissolved air and bubbles from the viscous solution. The solution had a viscosity of ˜50000 cP at room temperature. Film samples were made from this resin by coating the resin between a 2 mil thick ZF-50 and a 2 mil thick T50 silicone release coated polyester liner. The solution between films was drawn under a notch bar such a 175 um film was cast. The coating between liners was irradiated under low power 350 nm black light bulbs for 15 minutes to give a cured film with elastic or energy dissipation properties.

### Example 12

### Polyurethane Acrylate Resin and Film

Into a Flacktek Inc. size 20 speedmixer cup was added 99.5 g of CN3211 and 0.5 g of Irgacure TPO-L catalyst. The contents were mixed using a Flacktek DAC 150 FVZ-K speedmixer and were mixed at 3100 rpm for 1 min. The resulting solution was homogeneous near colorless viscous solution. The resulting solution was then placed into a vacuum oven at 40 Celsius and was degassed to remove all dissolved air and bubbles from the viscous solution. The solution had a viscosity of ˜25000 cP at room temperature. Film samples were made from this resin by coating the resin between a 2 mil thick ZF-50 and a 2 mil thick T50 silicone release coated polyester liner. The solution between films was drawn under a notch bar such a 175 um film was cast. The coating between liners was irradiated under low power 350 nm black light bulbs for 15 minutes to give a cured film with elastic or energy dissipation properties.

### Example 13

### Polyurethane Acrylate Resin (90/10) and Film

Into a Flacktek Inc. size 20 speedmixer cup was added 79.60 g of CN3211 (Sartomer, Inc.) and 19.90 g of SR501 (Sartomer, Inc.). The contents were mixed using a Flacktek DAC 150 FVZ-K speedmixer and were mixed at 3100 rpm for 1 min. The resulting solution was homogeneous near colorless viscous solution. To the speedmixer cup was added 0.5 g of Irgacure TPO-L catalyst. The contents were again mixed at 31000 rpm for 1 min. The resulting solution was then placed into a vacuum oven at 40 Celsius and was degassed to remove all dissolved air and bubbles from the viscous solution. The solution had a viscosity of ˜8500 cP at room temperature. Film samples were made from this resin by coating the resin between a 2 mil thick ZF-50 and a 2 mil thick T50 silicone release coated polyester liner. The solution between films was drawn under a notch bar such a 175 um film was cast. The coating between liners was irradiated under low power 350 nm black light bulbs for 15 minutes to give a cured film with elastic or energy dissipation properties.

### Example 14

### Polyurethane Acrylate Resin (80/20) and Film

Into a Flacktek Inc. size 20 speedmixer cup was added 79.60 g of CN3211 and 19.90 g of CD9043. The contents were mixed using a Flacktek DAC 150 FVZ-K speedmixer and were mixed at 3100 rpm for 1 min. The resulting solution was homogeneous near colorless viscous solution. To the speedmixer cup was added 0.5 g of TPO-L catalyst. The contents were again mixed at 31000 rpm for 1 min. The resulting solution was then placed into a vacuum oven at 40 Celsius and was degassed to remove all dissolved air and bubbles from the viscous solution. The solution had a viscosity of ˜5800 cP at room temperature. Film samples were made from this resin by coating the resin between a 2 mil thick ZF-50 and a 2 mil thick T50 silicone release coated polyester liner. The solution between films was drawn under a notch bar such a 175 um film was cast. The coating between liners was irradiated under low power 350 nm black light bulbs for 15 minutes to give a cured film with elastic or energy dissipation properties.

### Example 15

### Polyurethane Acrylate Resin (80/20) and Film

Into a Flacktek Inc. size 20 speedmixer cup was added 79.60 g of CN3211 and 19.90 g of SR415. The contents were mixed using a Flacktek DAC 150 FVZ-K speedmixer and were mixed at 3100 rpm for 1 min. The resulting solution was homogeneous near colorless viscous solution. To the speedmixer cup was added 0.5 g of TPO-L catalyst. The contents were again mixed at 31000 rpm for 1 min. The resulting solution was then placed into a vacuum oven at 40 Celsius and was degassed to remove all dissolved air and bubbles from the viscous solution. The solution had a viscosity of ˜5500 cP at room temperature. Film samples were made from this resin by coating the resin between a 2 mil thick ZF-50 and a 2 mil thick T50 silicone release coated polyester liner. The solution between films was drawn under a notch bar such a 175 um film was cast. The coating between liners was irradiated under low power 350 nm black light bulbs for 15 minutes to give a cured film with elastic or energy dissipation properties.

### Example 16

### Polyurethane Acrylate Resin (70/30) and Film

Into a Flacktek Inc. size 20 speedmixer cup was added 69.65 g of CN3211 and 29.85 g of SR531. The contents were mixed using a Flacktek DAC 150 FVZ-K speedmixer and were mixed at 3100 rpm for 1 min. The resulting solution was homogeneous near colorless viscous solution. To the speedmixer cup was added 0.5 g of Irgacure TPO-L catalyst. The contents were again mixed at 31000 rpm for 1 min. The resulting solution was then placed into a vacuum oven at 40 Celsius and was degassed to remove all dissolved air and bubbles from the viscous solution. The solution had a viscosity of ˜4000 cP at room temperature. Film samples were made from this resin by coating the resin between a 2 mil thick ZF-50 and a 2 mil thick T50 silicone release coated polyester liner. The solution between films was drawn under a notch bar such a 175 um film was cast. The coating between liners was irradiated under low power 350 nm black light bulbs for 15 minutes to give a cured film with elastic or energy dissipation properties.

### Example 17

### Polyurethane Acrylate Resin (80/20) and Film

Into a Flacktek Inc. size 20 speedmixer cup was added 79.60 g of CN3211 and 19.90 g of SR531. The contents were mixed using a Flacktek DAC 150 FVZ-K speedmixer and were mixed at 3100 rpm for 1 min. The resulting solution was homogeneous near colorless viscous solution. To the speedmixer cup was added 0.5 g of Irgacure TPO-L catalyst. The contents were again mixed at 31000 rpm for 1 min. The resulting solution was then placed into a vacuum oven at 40 Celsius and was degassed to remove all dissolved air and bubbles from the viscous solution. The solution had a viscosity of ˜5000 cP at room temperature. Film samples were made from this resin by coating the resin between a 2 mil thick ZF-50 and a 2 mil thick T50 silicone release coated polyester liner. The solution between films was drawn under a notch bar such a 175 um film was cast. The coating between liners was irradiated under low power 350 nm black light bulbs for 15 minutes to give a cured film with elastic or energy dissipation properties.

### Example 18

### Polyurethane Acrylate Resin (90/10) and Film

Into a Flacktek Inc. size 20 speedmixer cup was added 89.55 g of CN3211 (Sartomer, Inc.) and 9.95 g of SR531 (Sartomer, Inc.). The contents were mixed using a Flacktek DAC 150 FVZ-K speedmixer and were mixed at 3100 rpm for 1 min. The resulting solution was homogeneous near colorless viscous solution. To the speedmixer cup was added 0.5 g of Irgacure TPO-L catalyst. The contents were again mixed at 31000 rpm for 1 min. The resulting solution was then placed into a vacuum oven at 40 Celsius and was degassed to remove all dissolved air and bubbles from the viscous solution. The solution had a viscosity of ˜6000 cP at room temperature. Film samples were made from this resin by coating the resin between a 2 mil thick ZF-50 and a 2 mil thick T50 silicone release coated polyester liner. The solution between films was drawn under a notch bar such a 175 um film was cast. The coating between liners was irradiated under low power 350 nm black light bulbs for 15 minutes to give a cured film with elastic or energy dissipation properties.

TABLE 6
Properties of crosslinked polyurethane core layer materials

| | | | | | Tg by E″ | |
|---|---|---|---|---|---|---|
| | | | | | (° C.) | Storage |
| | | Oligomer to | Tg (° C.) | | (from DMA | Modulus |
| | Oligomer/ | Diluent | (Peak | | Storage | (MPa) |
| Example | Diluent | Ratio | Tan δ) | Tan δ | Modulus) | (23° C./−20° C.) |
| 11 | CN9004/ | 100/0 | −67 | 0.614 | −73.6 | 7.42/9.86 |
| | NA | | | | | |
| 12 | CN3211/ | 100/0 | −20.7 | 1.473 | −29.7 | 2.87/27.4 |
| | NA | | | | | |
| 13 | CN3211/ | 80/20 | −5.24 | 0.639 | −25.1 | 7.74/515.9 |
| | SR501 | | | | | |
| 14 | CN3211/ | 80/20 | −24.1 | 1.390 | −32.3 | 3.59/15.99 |
| | CD9043 | | | | | |
| 15 | CN3211/ | 80/20 | −21.5 | 1.334 | −28.8 | 5.09/31.22 |
| | SR415 | | | | | |
| 16 | CN3211 / | 70/30 | −5.5 | 1.334 | −22.9 | 1.80/711.9 |
| | SR531 | | | | | |
| 17 | CN3211/ | 80/20 | −11.0 | 1.359 | −24.9 | 2.23/360.1 |
| | SR531 | | | | | |
| 18 | CN3211/ | 90/10 | −16.7 | 1.398 | −27.3 | 2.39/97.4 |
| | SR531 | | | | | |

Dynamic Mechanical Analysis Test Method

Samples were cut into strips 6.35 mm wide and about 4 cm long. The thickness of each film was measured. The films were mounted in the tensile grips of a Q800 DMA from TA Instruments with an initial grip separation between 16 mm and 19 mm. The samples were then tested at an oscillation of 0.2% strain and 1 Hz throughout a temperature ramp from −20° C. to 200° C. at a rate of 2° C. per minute. The temperature at which the Tan Delta signal reached a maximum was recorded as the peak Tan Delta temperature. Glass transition temperatures were taken from peak of E″.

### Examples 19-23

### Polyurethane Resin and Film

Preparation of polyol with catalyst—in a standard mixer equipped with a low shear blade was placed 200 lbs of K-FLEX 188 and 42 grams of DABCO T-12. The components were mixed under vacuum for 4 hours at 70 degrees Celsius and 28 inches of mercury to reduce gas in the resin. The resulting resin was placed into a container for later use.

Preparation of DESMODUR N3300—in a standard mixer equipped with a low shear blade was placed 200 lbs of DESMODUR 3300. The component was mixed under vacuum for 4 hours at 140 degrees Celsius and 28 inches of mercury to reduce gas in the resin. The resulting resin was placed into a container for later use.

The polyol with catalyst and DESMODUR 3300 were added to separate pump carts with mass flow controllers. The polyol with catalyst was heated to 60 degrees Celsius to lower its viscosity. The two components were delivered in controlled stoichiometry from the pump carts via mass flow control to a static mixer. The polyurethane reactive mixture was placed between 12 inch wide T-50 liners and the films were pulled under a notch bar with a gap set to produce a polyurethane coating with an about 3 mil thickness in a continuous fashion. The assembly was heated to gel the polyurethane film and was placed in a 70 degree Celsius oven for 16 hours to cure. Prior to testing, the liners were removed.

The cross-link density of the cured polyurethane coatings was calculated using the method described in Macromolecules, Vol. 9, No. 2, pages 206-211 (1976). To implement this model, integral values for chemical functionality are required. DESMODUR N3300 is reported to have an average functionality of 3.5 and an isocyanate equivalent weight of 193 g/equiv. This material was represented in the mathematical model as a mixture of 47.5 wt % HDI trimer (168.2 g/equiv), 25.0% HDI tetramer (210.2 g/equiv), and 27.5 wt % HDI pentamer (235.5 g/equiv). This mixture yields an average equivalent weight of 193 g/equiv., and an average functionality of 3.5.

TABLE 7
Coating composition and theoretical crosslink concentration

| | | | | | Theoretical |
|---|---|---|---|---|---|
| | Polyol with | DESMODUR | | Theoretical | Crosslink |
| | catalyst | 3300 | NCO/OH | Gel Content | Concentration |
| Example | (g/min) | (g/min) | Ratio | (%) | (mol/kg) |
| 19 | 32.77 | 20.74 | 0.8 | 96.7 | 0.34 |
| 20 | 32.77 | 22.03 | 0.85 | 98.3 | 0.42 |
| 21 | 32.77 | 23.33 | 0.9 | 99.3 | 0.49 |
| 22 | 32.77 | 24.62 | 0.95 | 99.8 | 0.57 |
| 23 | 32.77 | 25.92 | 1 | 100 | 0.65 |
| C1 | 32.77 | 18.14 | 0.7 | 90.7 | 0.21 |
| C2 | 32.77 | 19.44 | 0.75 | 94.2 | 0.27 |
| C3 | 32.77 | 27.22 | 1.05 | 100 | 0.61 |

### Example A

### Silver Nanowire on Unprimed ST-504 PET

A mixture composed of 95% by weight Cambrios CLEAROHM™ Generation 5 (available from Cambrios Technologies Corporation, Sunnyvale, Calif.) 1% silver nanowire aqueous solution and 5% by weight isopropyl alcohol (available from Sigma Aldrich, St. Louis, Mo.) was mixed by agitation in a 1 liter clear bottle to yield a coating formulation referred to as a nanowire formulation.

The nanowire formulation was coated 4 inches wide onto the unprimed side of 5 mil thick polyethylene terephthalate (PET) substrate (MELINEX ST-504 film, available from DuPont, Wilmington, Del.) using a slot die, targeting a pre-metered wet film thickness of approximately 20 μm at a web speed of 3.0 m/min to form a nanowire layer on the substrate. The nanowire layer was then heated to a temperature of 90 degrees C. in air impingement oven for approximately 2 minutes, which resulted in a coated and dried transparent and electrically conductive nanowire layer. The sheet resistance was measured to be between 50 and 75 Ohms/Sq., as determined by a two-point probe measurement.

A hand spread coating of the transparent energy dissipation layer (polyurethane) described as Examples 19-23 of Table 7 was applied on top of the nanowire coating and allowed to cure in an oven. After curing, the optically clear transparent energy dissipation layer (polyurethane) was peeled from the PET substrate with the nanowires embedded in it. The embedded nanowires retain conductivity even after a creasing event.

### Example B

### Coating of Dual Side Silver Nanowire on Primed ST-505 PET and Silicone Printing

Step 1: Coating of Silver Nanowire Substrate

A mixture composed of 95% by weight Cambrios CLEAROHM™ Generation 5 (available from Cambrios Technologies Corporation, Sunnyvale, Calif.) 1% silver nanowire aqueous solution and 5% by weight isopropyl alcohol (available from Sigma Aldrich, St. Louis, Mo.) was mixed by agitation in a 5 gallon pail to yield a coating formulation referred to as a nanowire formulation.

The nanowire formulation was coated over 13″ inches wide onto 5 mil thick polyethylene terephthalate (PET) substrate (MELINEX ST-505 film, available from DuPont, Wilmington, Del.) using a slot die, targeting a pre-metered wet film thickness of approximately 20 μm at a web speed of 40 ft/min to form a nanowire layer on the substrate. The nanowire layer was then heated to a temperature of 100 degrees C. in air impingement oven for approximately 2 minutes, which resulted in a coated and dried transparent and electrically conductive nanowire layer. The sheet resistance was measured to be between 50 and 75 Ohms/Sq., as determined by a two-point probe measurement.

Step 2: Printing of Silicone Resist Layer

A silicone ink mixture composed of 97.5% by weight Sly-Off(R)2-7170 and 2.5% by weight Sly-Off(R)7488 cross-linker (Dow Corning Corporation, Midland, Mich.) was deposited onto the nanowire-coated substrate by flexographic printing as a resist matrix material, using a patterned photopolymer stamp. The printed pattern consisted of an array of squares ranging in size from 100 um to 500 um with spaces ranging between 100 um and 500 um in both the horizontal and vertical directions. The flexographic tool used to make the pattern was fabricated by Southern Graphics Systems (SGS, Minneapolis, Minn.) based on an image that defined the pattern. The silicone resist matrix material was printed at a speed of 10 ft/min, using a 1.0 BCM/sq. in. ANILOX roll (rated to give a wet coating of approximately 0.3 to 2.0 μm). The patterned thermally-curable printing ink matrix material was thermally cured using an air impingement oven set to 275 F. and an IR oven, until the silicone ink was sufficiently cured to the touch.

Step 3: Application of Shape-Memory Polyurethane and Separation to Pattern

A coating of the transparent energy dissipation layer (polyurethane) described as Examples 19-23 of Table 7 was applied on top of the nanowire coating with silicone print and allowed to cure in an oven. After curing the optically clear shape memory material was peeled from the PET substrate with the nanowires embedded in it where there had not been any silicone material. The nanowires embedded in the shape memory polyurethane retain conductivity even after a creasing event or repeated folding events.

### Example C

### Printing of PChem PFI-722 Silver Nanoparticle Ink on Loparex Silicone Liner

NovaCentrix PFI-722 silver nanoparticle conductive ink was deposited onto the Easy Side of 3 mil Loparex PRIMELINER™ PET substrate by flexographic printing, using a patterned photopolymer stamp. The printed pattern consisted of an array of lines ranging in width from 100 um to 500 um on a pitch ranging between 300 um and 1000 um in the printed down-web direction. The flexographic tool used to make the pattern was fabricated by Southern Graphics Systems (SOS, Minneapolis, Minn.) based on an image that defined the pattern. The PFI-722 silver nanoparticle ink was printed at a speed of 25 ft/min, using a 4.0 BCM/sq. in. ANILOX roll (rated to give a wet coating of approximately 0.5 to 3.0 μm). The patterned silver ink was dried and thermally cured using two air impingement ovens set to 275 degrees F., until the silver ink was sufficiently dry and cured to the touch.

A coating of the transparent energy dissipation layer (polyurethane) described as Examples 19-23 of Table 7 was applied on top of the printed material and allowed to cure in an oven. After curing, the shape-memory material was peeled from the liner with the silver ink embedded inside.

### Example D

### Comparative: Coating onto Shape-Memory Polyurethane

A coating of the transparent energy dissipation layer (polyurethane) described as Examples 19-23 of Table 7, was prepared and a hand spread of Cambrios CLEAROHM™ Generation 5 Ink (available from Cambrios Technologies Corporation, Sunnyvale, Calif.) was applied to the exposed polyurethane. This ink was approximately 1% solids (silver nanowire) in approximately 90 to 10 mixture of water and isopropyl alcohol. A RDS-12 Meyer rod was used to draw the hand spread. After coating the sample was dried in an oven at 90° C. for 3 minutes. The resulting film remained optically clear.

### Example E

### Between Patterned Touch Sensors

Rolls of touch sensor patterned web was obtained by the processes described in WO2014/088950A1 which included patterned silver nanowire transparent electrodes and silver ink printed interconnects on ST504 PET as described in Example A. The coating of the transparent energy dissipation layer (polyurethane) described as Examples 19-23 of Table 7 was coated in between the webs of the two touch sensor layers with the sensor patterns facing each other. Freshly made samples could be peeled apart leaving the shape memory material with the two touch sensor patterns including interconnects on each side.

Thus, embodiments of FLEXIBLE CONDUCTIVE DISPLAY FILM are disclosed.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof. The disclosed embodiments are presented for purposes of illustration and not limitation.

1. A display film comprising:
a transparent energy dissipation layer having a glass transition temperature of 27 degrees Celsius or less and a Tan Delta peak value of 0.5 or greater; and
a transparent conductor layer disposed on the transparent energy dissipation layer.

2. The display film according to claim 1, wherein the transparent conductor layer comprises a plurality of nanowires.

3. The display film according to claim 1, wherein the transparent conductor layer comprises a pattern of nanowires.

4. The display film according to claim 1, wherein the transparent conductor layer comprises silver nanowires having a diameter of 100 nanometers or less.

5. The display film according to claim 1, further comprising a second transparent conductor layer disposed on the transparent energy dissipation layer, wherein the transparent energy dissipation layer separates the transparent conductor layers.

6. The display film according to claim 5, wherein the second transparent conductor layer comprises a plurality of nanowires forming a pattern.

7. The display film according to claim 5, wherein the second transparent conductor layer comprises silver nanowires having a diameter or lateral distance of 100 nanometers or less.

8. The display film according to claim 6, wherein the second transparent conductor layer pattern comprises linear extending traces that are orthogonal to the transparent conductor layer plurality of nanowires comprising linear extending traces.

9. The display film according to claim 1, wherein the transparent conductor layer is embedded within the transparent energy dissipation layer.

10. The display film according to claim 6, wherein the transparent conductor layer comprises a plurality of nanowires embedded within the transparent energy dissipation layer and the second transparent conductor layer comprises a plurality of nanowires embedded within the transparent energy dissipation layer.

11. The display film according to claim 1, wherein the transparent energy dissipation layer comprises cross-linked polyurethane or cross-linked polyurethane acrylate or cross-linked polyurethane and polyacrylate.

12. The display film according to claim 1, wherein the display film has a haze value of less than 5%, or less than 3%, or less than 2%, or less than 1%, and the display film has a visible light transmission value greater than 85%, or greater than 90%, and the display film has a clarity value greater than 90%, or greater than 95% or greater than 98%.

13. The display film according to claim 1, wherein the transparent energy dissipation layer has a glass transition temperature of 25 degrees Celsius or less, or 20 degrees Celsius or less, or 15 degrees Celsius or less, 10 degrees Celsius or less, 5 degrees Celsius or less, or 0 degrees Celsius or less, or −5 degrees Celsius or less, or in a range from −40 to 15 degrees Celsius, or in a range from −30 to 15 degrees Celsius, or in a range from −30 to 10 degrees Celsius, or in a range from −30 to 5 degrees Celsius, or in a range from −30 to 0 degrees Celsius, or in a range from −20 to 0 degrees Celsius.

14. The display film according to claim 1, wherein the transparent energy dissipation layer has a Tan Delta peak value of 0.8 or greater, or 1.0 or greater, or 1.2 or greater, or in a range from 0.5 to 2.5, or in a range from 1 to 2.5.

15. A display film comprising:
a transparent energy dissipation layer having a glass transition temperature of 27 degrees Celsius or less and a Tan Delta peak value of 0.5 or greater, and defining a first major surface and an opposing second major surface;
a transparent conductor layer disposed on the first major surface of the transparent energy dissipation layer;
a protective layer disposed on the second major surface.

16. The display film according to claim 15, wherein the transparent conductor layer comprises a plurality of nanowires.

17. The display film according to claim 15, wherein the transparent conductor layer comprises a pattern of conductive regions.

18. The display film according to claim 15, wherein the transparent conductor layer comprises silver nanowires having a diameter of 100 nanometers or less.

19. The display film according to claim 15, wherein the transparent conductor layer comprises a plurality of nanowires embedded within the transparent energy dissipation layer.

20. The display film according to claim 15, wherein the protective layer comprises nanoparticles and has a thickness in a range from 2 to 30 micrometers, or from 2 to 15 micrometers, or from 3 to 10 micrometers.

21. The display film according to claim 15, wherein the protective layer comprises a glass layer having a thickness in a range from 15 to 500 micrometers, or from 20 to 120 micrometers, or from 30 to 100 micrometers, or from 30 to 80 micrometers.

22. The display film according to claim 15, further comprising an adhesive layer disposed on the transparent conductor layer.

23. The display film according to claim 15, wherein the display film has a thickness of less than 500 micrometers, or less than 300 micrometers, or less than 200 micrometers, or in a range from 85 to 350 micrometers or from 100 to 250 micrometers or from 100 to 200 micrometers.

24. The display film according to claim 15, wherein the transparent energy dissipation layer comprises cross-linked polyurethane or cross-linked polyurethane acrylate or cross-linked polyurethane and polyacrylate.

25. The display film according to claim 15, wherein the display film has a haze value of less than 5%, or less than 3%, or less than 2%, or less than 1%, and the display film has a visible light transmission value greater than 85%, or greater than 90%, and the display film has a clarity value greater than 90%, or greater than 95% or greater than 98%.

26. The display film according to claim 15, wherein the transparent energy dissipation layer has a glass transition temperature of 25 degrees Celsius or less, or 20 degrees Celsius or less, or 10 degrees Celsius or less, or 5 degrees Celsius or less, or 0 degrees Celsius or less, or −5 degrees Celsius or less, or in a range from −40 to 15 degrees Celsius, or in a range from −30 to 15 degrees Celsius, or in a range from −30 to 10 degrees Celsius, or in a range from −30 to 5 degrees Celsius, or in a range from −30 to 0 degrees Celsius, or in a range from −20 to 0 degrees Celsius.

27. The display film according to claim 15, wherein the transparent energy dissipation layer has a Tan Delta peak value of 0.8 or greater, or 1.0 or greater, or 1.2 or greater, or in a range from 0.5 to 2.5, or in a range from 1 to 2.5.

28. An article, comprising:
an optical display;
a display film, according to claim 1, fixed to the optical display.

29. The article according to claim 28, wherein the optical display comprises organic light emitting diodes.

30. The article according to claim 28, wherein the optical display and display film is foldable so that the optical display faces itself and at least a portion of the display film overlaps with another portion of the display film.

31. The article according to claim 28, wherein the optical display is fixed to the display with an optical adhesive.
